(19) United States
(12) Patent Application Publication
(10) Pub. No.: US 2009/0072315 A1
(43) Pub. Date: Mar. 19, 2009

(54) Semiconductor Manufacturing Process Charge Protection Circuits

(76) Inventors: Uwe Hodel, Munich (DE); Peter Baumgartner, Munich (DE)

Correspondence Address: SLATER & MATSIL LLP, 17950 PRESTON ROAD, SUITE 1000, DALLAS, TX, 75252, US

(21) Appl. No.: 11/854,893

(22) Filed: Sep. 13, 2007

(51) Int. Cl. H01L 23/62; H01L 21/336

(52) U.S. Cl. 257/356; 438/197; 257/E27.06; 257/E27.107

(57) ABSTRACT

Embodiments of the invention relate to semiconductor manufacturing process charge protection circuits, integrated circuits and to methods for manufacturing a semiconductor manufacturing process charge protection circuit. In an embodiment of the invention, a charge protection circuit includes a first terminal coupled to a charge receiving region, a second terminal providing a discharge path, and a rectifying circuit coupled between the first terminal and the second terminal, the rectifying circuit including at least two anti-parallel coupled rectifying components.

### TECHNICAL FIELD

Embodiments of the invention relate to semiconductor manufacturing process charge protection circuits, integrated circuits and to methods for manufacturing a semiconductor manufacturing process charge protection circuit.

### BACKGROUND

Plasma processes in CMOS (Complementary Metal Oxide Semiconductor) logic (etchings or depositions) may lead to a strong charge loading on photoresists, metals and semiconductor surfaces. When these charges are in contact with, e.g., a gate oxide of a field effect transistor, they can lead to oxide degradation or oxide destruction. Since it is not possible to predict which polarity the charge loadings are, it is desired to protect the components during the manufacturing process thereof against the charge loadings of both polarities.

To protect, e.g., a gate oxide from high voltages during a manufacturing process, usually diodes are placed between the gate of a field effect transistor and the substrate. During a plasma etch, these diodes become conducting due to the presence of UV (ultra violet) radiation. Thus, the metal line which contacts the gate can be uncharged via the conducting diode and the oxide would not be harmed.

Proper protection usually requires very large diodes which form a large parasitic capacitance at the protected node of an integrated circuit. Thus, they present a parasitic impedance to the ground node of the integrated circuit.

In addition to the parasitic impedance, these structures may also be troublesome when making Radio Frequency (RF) S-parameter measurements, e.g., due to the bad ratio between capacitance of measurement pads (plus antenna diode) and the device to be measured.

With further miniaturization, the charging problems are expected to increase.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows an integrated circuit in accordance with an embodiment of the invention;

FIG. 2 shows an embodiment of a portion of the integrated circuit shown in FIG. 1 in accordance with an embodiment of the invention;

FIGS. 3A and 3B show current/voltage diagrams of diodes in accordance with an embodiment of the invention, wherein FIG. 3A shows a current/voltage diagram illustrating the characteristics of different numbers of serially coupled diodes in the range from about 600 mA to about −600 mA, and FIG. 3B shows a current/voltage diagram illustrating the characteristics of different numbers of serially coupled diodes in the range from about 1 A to about 10⁻¹³ MA;

FIGS. 4A and 4B show current/voltage diagrams of diodes in accordance with an embodiment of the invention, wherein FIG. 4A shows a current/voltage diagram illustrating the characteristics of different numbers of serially coupled diodes in the range from about 300 mA to about −300 mA, and FIG. 4B shows a current/voltage diagram illustrating the characteristics of different numbers of serially coupled diodes in the range from about 1 A to about 10⁻¹⁶ mA;

FIG. 5 shows a plurality of serially coupled pn diodes in accordance with an embodiment of the invention;

FIG. 6 shows a plurality of serially coupled np diodes in accordance with another embodiment of the invention;

FIG. 7 shows the current paths for electrically discharging for different polarities for the plurality of serially coupled pn diodes shown in FIG. 5 in accordance with an embodiment of the invention;

FIG. 8 shows the current paths for electrically discharging for different polarities for the plurality of serially coupled np diodes shown in FIG. 6 in accordance with an embodiment of the invention;

FIG. 9 shows a small signal equivalent circuit of a diode subcircuit in accordance with an embodiment of the invention; and

FIG. 10 shows an embodiment of a protection circuit portion of an integrated circuit in accordance with an embodiment of the invention, wherein only one polarity of protection is realized.

### DETAILED DESCRIPTION OF ILLUSTRATIVE EMBODIMENTS

As used herein the terms connected and coupled are intended to include both direct and indirect connection and coupling, respectively.

Conventionally, antenna charging has been avoided by placing a protection diode with sufficient size between a metal and a substrate. Either this diode would lead the current in forward mode or would become conducting due to the UV radiation. Therefore, the metals connected to a protection diode would be discharged and voltage peaks are avoided. The conventional protection diode should be chosen large enough, so that in the case of conduction, the electrical resistance of the protection diode is small enough and a voltage drop is not large enough to harm the electronic element to be protected, e.g., the gate oxide of a field effect transistor to be protected.

In practice, using one protecting diode may lead to the usage of very large antenna protection diodes to avoid device degradation. By way of example, in accordance with a design rule, the minimum area of a protection diode is about 1/20 of the area provided for the metal in the integrated circuit. The result may be that it may be difficult to produce proper RF measurements with sufficient or full antenna protection (in an RF measurement, the device gate is contacted directly to a contact pad).

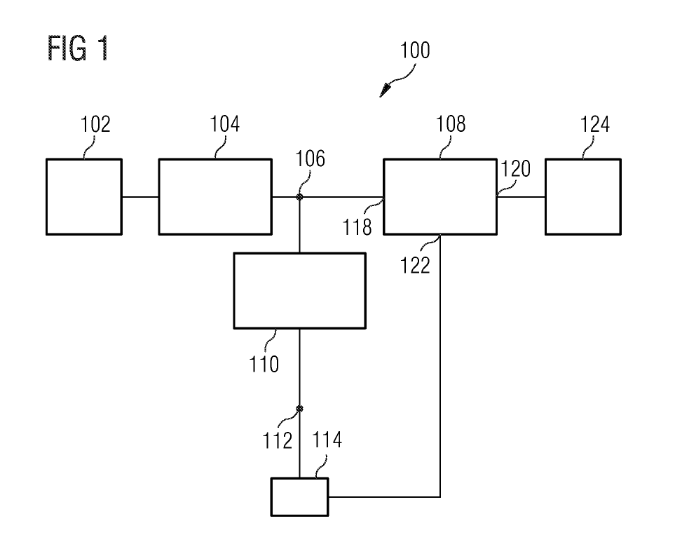

In an embodiment of the invention, as shown in FIG. 1, an integrated circuit 100 includes a circuit 102 having antenna characteristics.

In an embodiment of the invention, the circuit 102 may be a high frequency circuit such as, e.g., an oscillator circuit having at least one coil, alternatively, e.g., an amplifier circuit (e.g., a low noise amplifier circuit) having at least one coil. The circuit 102 may be positioned in a charge receiving region 104 or may be coupled to the charge receiving region 104. In an alternative embodiment, the circuit 102 may be omitted and only the charge receiving region 104 may be provided.

In an embodiment of the invention, electrical charge carriers are received in the charge receiving region 104, which may have antenna characteristics, during a semiconductor manufacturing process to manufacture a semiconductor arrangement. In various embodiments of the invention, the charge receiving region 104 may include one or more of photoresist material, metal or other electrically conducting or semiconducting material that may receive electrical charge carriers. The electrical charge carriers may be generated, e.g., during a semiconductor manufacturing process, e.g., during a plasma process (e.g., during an etch process or a deposition process or any other provided plasma process) carried out, e.g., in the metallization regions of an integrated circuit during the manufacturing thereof, e.g., during the manufacturing of logic circuits or memory circuits. However, the embodiments of the invention are not limited to such processes but are applicable to any process in which electrical charge carriers are generated and one or more electrical elements should be protected against the charge carriers, e.g., against an overcharge. In an embodiment of the invention, the charge receiving region 104 may include one or more contacting pads of the integrated circuit 100.

In an embodiment of the invention, the integrated circuit 100 further includes a first terminal (also referred to as first node) 106 which is coupled to the charge receiving region 104 such that the charge carriers received by the charge receiving region 104 can move to the first terminal 106, thereby changing its electrical potential. Furthermore, the integrated circuit 100 may include an electronic element 108 which is coupled to the first terminal 106. The electronic element 108 should be protected against an overcharge, i.e., protected against too many charge carriers present at the first terminal 106 and thus against an overvoltage (a too high electrical potential) which may occur at the first terminal 106.

In an embodiment of the invention, the electronic element 108 may be a transistor such as a bipolar transistor or a field effect transistor. The field effect transistor may be any type of field effect transistor such as, e.g., a MIS (Metal Insulator Semiconductor) field effect transistor, a MOS (Metal Oxide Semiconductor) field effect transistor, a CMOS (Complementary Metal Oxide Semiconductor) field effect transistor, etc. Furthermore, the field effect transistor may be provided in any kind of structure such as, e.g., a planar field effect transistor, a vertical field effect transistor or a fin field effect transistor. The field effect transistor may have one gate or a plurality of gates located adjacent to the channel region of the field effect transistor. In an embodiment of the invention, the field effect transistor has a gate oxide disposed above the channel region and a gate region disposed above the gate oxide. In this embodiment, e.g. the gate insulating material (e.g., the gate oxide) is protected against an overvoltage at the first terminal 106. In another embodiment, the control terminal (e.g., 118) (e.g., the base terminal of a bipolar transistor or the gate region of a field effect transistor) of the transistor is coupled to the first terminal 106.

Furthermore, a rectifying circuit, e.g. a diode circuit 110, is provided and coupled with the first terminal 106 on the one side (also referred to as input side) of the diode circuit 110 and with a second terminal 112 on the opposite side (also referred to as output side) of the diode circuit 110.

In an embodiment of the invention, the second terminal 112 is coupled to a reference potential, e.g., the ground potential 114, e.g., the circuit ground potential 114.

In an embodiment of the invention, the first terminal 106, the diode circuit 110 and the second terminal 112 form a semiconductor manufacturing process charge protection circuit to protect the electronic element 108, e.g., against an overvoltage at the first terminal 106, e.g., occurring during a semiconductor manufacturing process as described above.

As will be described in more detail below, the rectifying circuit, e.g., the diode circuit 110, is coupled between the first terminal 106 and the second terminal 112 and may include at least two anti-parallel coupled rectifying components such as, e.g., at least two anti-parallel coupled diodes. In an alternative embodiment of the invention, the rectifying circuit may include at least two anti-parallel coupled other rectifying components such as, e.g., transistors in a rectifying coupling structure (e.g., a MOS field effect transistor in diode connection) or thyristors coupled in a rectifying coupling structure or providing a rectifying functionality.

In yet another embodiment of the invention, the rectifying circuit may include a plurality of serially coupled rectifying components, wherein the rectifying components are all connected in the same flow direction. In an embodiment of the invention, the rectifying circuit may include a first rectifying subcircuit having a plurality of serially coupled rectifying components, wherein the rectifying components of the first rectifying subcircuit are all connected in the same flow direction, and a second rectifying subcircuit having a plurality of serially coupled rectifying components, wherein the rectifying components of the second rectifying subcircuit are all connected in the same flow direction.

In the embodiment, in which the electronic element 108 is a transistor, a first controlled terminal 120 (e.g., an emitter terminal or a collector terminal of a bipolar transistor or a source/drain region of a field effect transistor) may be coupled to a load circuit 124 (e.g., one more logic circuits or one or more memory circuits) and the respective second controlled terminal 122 of the transistor may be coupled to the reference potential 114.

As will be described in more detail below, in an embodiment of the invention, the diode circuit 110 includes a first diode subcircuit having a plurality of serially coupled diodes (in general, a plurality of serially coupled rectifying components), wherein the diodes of the first diode subcircuit are all connected in the same flow direction, and a second diode subcircuit comprising a plurality of serially coupled diodes (in general, a plurality of serially coupled rectifying components), wherein the diodes of the second diode subcircuit are all connected in the same flow direction. In an embodiment of the invention, the diodes of the first diode subcircuit are coupled anti-parallel to the diodes of the second diode subcircuit.

In a particular embodiment of the invention, the diodes of the first diode subcircuit are pn-diodes, wherein the p-terminal of a first diode of the first diode subcircuit is coupled to the first terminal and the n-terminal of a last diode of the first diode subcircuit is coupled to the second terminal, and the diodes of the second diode subcircuit are np-diodes, wherein the n-terminal of a first diode of the second diode subcircuit is coupled to the first terminal and the p-terminal of a last diode of the second diode subcircuit is coupled to the second terminal. It should be mentioned that in various embodiments of the invention, any type of diodes may be used, e.g., pn-diodes or no-diodes (i.e., diodes having a pn-junction or an np-junction), PIN diodes, Schottky diodes, Zener-diodes, Avalanche diodes, Esaki diodes, etc. In an embodiment of the invention, diodes may be used which show an exponential voltage/current characteristic. As mentioned above, in an alternative embodiment of the invention, instead of diodes, other rectifying components may be used such as, e.g., transistors in a rectifying coupling structure (e.g., a MOS field effect transistor in diode connection) or thyristors coupled in a rectifying coupling structure or providing a rectifying functionality.

Illustratively, embodiments of the invention provide a protection scheme which can properly protect an electronic element such as, e.g., a transistor while having only small parasitics.

In an embodiment of the invention, the conventionally occurring high parasitic capacitance is reduced by a new protection concept. The protection may be realized by an anti-parallel arrangement of series pn-diodes and np-diodes as will be described in more detail below. The voltage when these series diode stack becomes forward biased can be adjusted by selecting the appropriate number of diodes. One effect of using the diode stack having a plurality of serially coupled diodes is that the parasitic capacitance is much smaller than in the case of using a single diode. By means of the arrangement of diodes being a serial arrangement, the overall capacitance may be further reduced.

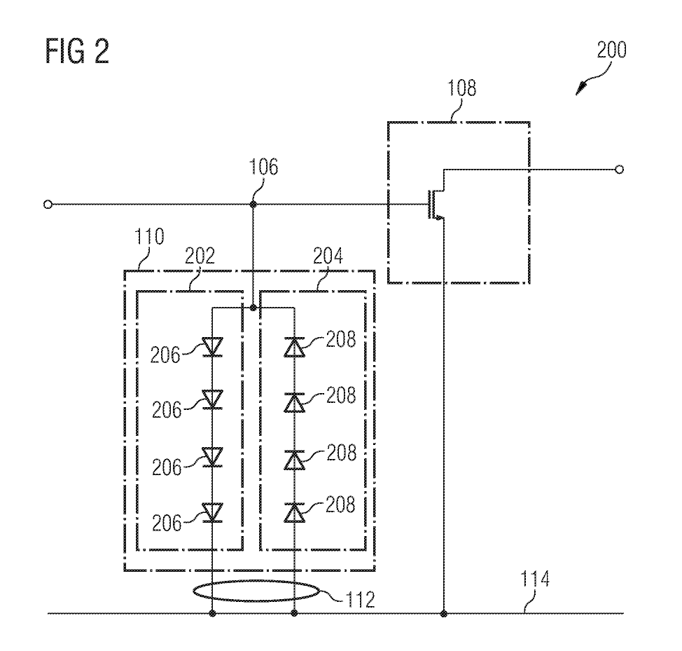

FIG. 2 shows an embodiment of a portion 200 of the integrated circuit 100 shown in FIG. 1 in accordance with an embodiment of the invention.

As shown in FIG. 2, the electronic element 108 is embodied as a transistor, e.g., as a MOS field effect transistor, e.g., as a CMOS field effect transistor, e.g., the gate oxide of which should be protected against damage that may occur due to an overcharge at the first terminal 106. As described above, the first terminal 106 may be coupled to the charge receiving region 104. Thus, illustratively, in an embodiment of the invention, the first terminal 106 provides a gate connection (of the MOS field effect transistor) to an antenna relevant metal area of an integrated circuit, in other words, to a metal area which shows antenna characteristics.

In the embodiment shown in FIG. 2, the diode circuit 110 includes a plurality of, e.g., two diode subcircuits, e.g., a first diode subcircuit 202 and a second diode subcircuit 204. The first diode subcircuit 202 includes a plurality of first diodes 206 being serially coupled with each other, wherein the diodes of the first diode subcircuit 202 are all connected in the same flow direction, i.e., an n-region of one first diode 206 is connected to the p-region of the following first diode 206 of the serial connection of the first diode subcircuit 202. As shown in FIG. 2, the p-region of the first diode 206 of the first diode subcircuit 202 is connected to the first terminal 106 and the n-region of the last first diode 206 of the first diode subcircuit 202 is connected to the second terminal 112. Furthermore, the second diode subcircuit 204 includes a plurality of second diodes 208 being serially coupled with each other, wherein the diodes of the second diode subcircuit 204 are all connected in the same flow direction, i.e. an n-region of one second diode 208 is connected to the p-region of the following second diode 208 of the serial connection of the second diode subcircuit 204. As shown in FIG. 2, the n-region of the first second diode 208 of the second diode subcircuit 204 is connected to the first terminal 106 and the p-region of the last second diode 208 of the second diode subcircuit 204 is connected to the second terminal 112. Thus, the first diode subcircuit 202 and the second diode subcircuit 204 are coupled anti-parallel to one another. The number of first diodes 206 and second diodes 208 may be arbitrarily selected, although in this example, four first diodes 206 and four second diodes 208 are provided. The number of first diodes 206 and second diodes 208 may be equal, in an alternative embodiment of the invention, however, the numbers of the first diodes 206 and second diodes 208 may be different. Furthermore, the first diodes 206 may all have the same size and characteristics (e.g., doping profile) or they may be provided having different sizes and/or characteristics. In a similar manner, the second diodes 208 may all have the same size and characteristics (e.g., doping profile) or they may be provided having different sizes and/or characteristics.

As already mentioned above, in an alternative embodiment of the invention, the first diode subcircuit 202 and/or the second diode subcircuit 204 may each include only one first diode 206 and second diode 208, respectively.

By selecting the number and type/size/characteristics of the provided first diode(s) 206 and/or second diode(s) 208, the provided leakage current and current flow characteristic may be selected and adapted to the application dependent requirements.

In an embodiment of the invention, the properties of serially coupled diodes are used.

By way of example, the exponential current voltage curves of the used diodes 206, 208 allow the adjustment of the onset of the forward current by choosing the right number of diodes 206, 208 (for example, if oxides with different voltage hardness are used). By using two anti-parallel diode stacks (e.g., the first diode subcircuit 202 and the second diode subcircuit 204), a protection is realized for any polarity of charging. The forward current of a diode can be much larger than the protection current of a conventional antenna protection diode during UV induced conduction. Thus, in an embodiment of the invention, a protection can be realized with much smaller diodes, thereby providing a less parasitic capacitance.

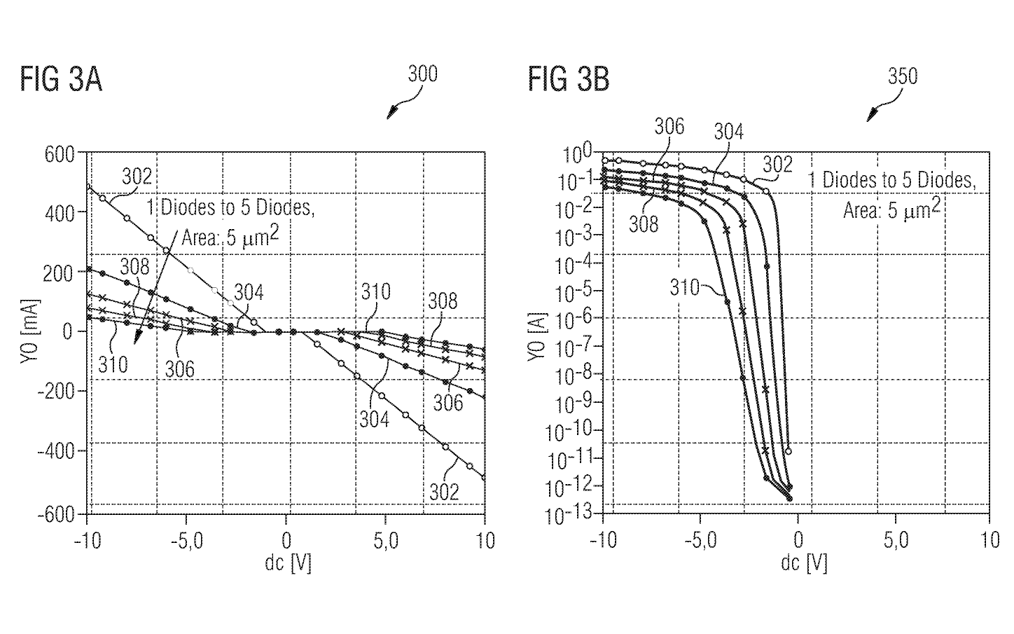

As described above, in an embodiment of the invention, anti-parallel diode stacks (e.g., the first diode subcircuit 202 and the second diode subcircuit 204) are used. Thus, always one of the diode stacks is forward biased, as shown in FIGS. 3A and 3B.

FIGS. 3A and 3B show current/voltage diagrams of diodes in accordance with an embodiment of the invention. FIG. 3A shows a first current/voltage diagram 300 illustrating the characteristics of different numbers of serially coupled diodes in the range from about 600 mA to about −600 mA in linear scale. FIG. 3B shows a second current/voltage diagram 350 illustrating the characteristics of different numbers of serially coupled diodes in the range from about 1 A to about 10⁻¹³ mA in logarithmic scale. In both current/voltage diagrams 300, 350, a voltage range from about −10 V to about 1 V is shown. The simulated voltage curves are shown for a combination of np and pn diodes each having a diode area of 5 μm². The number of diodes in series has been varied. In an embodiment of the invention, the simulation has been based on junction diode models with integrated scalable series resistance.
In more detail, the current/voltage diagrams 300, 350 show
a first current/voltage curve 302 representing one diode,
a second current/voltage curve 304 representing two serially coupled diodes,
a third current/voltage curve 306 representing three serially coupled diodes,
a fourth current/voltage curve 308 representing four serially coupled diodes, and
a fifth current/voltage curve 310 representing five serially coupled diodes.

As can be seen from the FIGS. 3A and 3B, by selecting different numbers of serially coupled diodes, the serial resistance and the current/voltage characteristic of the serial connection can be adapted.

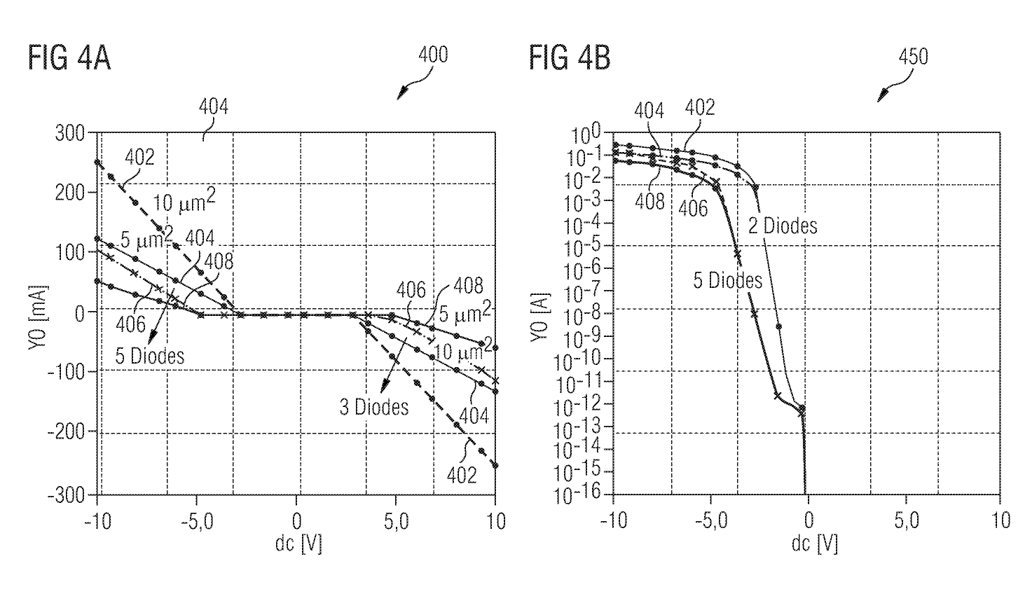

FIGS. 4A and 4B show current/voltage diagrams of diodes in accordance with an embodiment of the invention. FIG. 4A shows a third current/voltage diagram 400 illustrating the characteristics of different numbers of serially coupled diodes in the range from about 300 mA to about −300 mA in linear scale for different diode areas. FIG. 4B shows a fourth current/voltage diagram 450 illustrating the characteristics of different numbers of serially coupled diodes in the range from about 1 A to about 10⁻¹⁶ mA in logarithmic scale for different diode areas. In both current/voltage diagrams 400, 450, a voltage range from about −10 V to about 1 V is shown. The simulated voltage curves are shown for a combination of np and pn diodes having a diode area of 5 μm² and 10 μm². The number of diodes in series has been varied. In an embodiment of the invention, the simulation has been based on junction diode models with integrated scalable series resistance.

In more detail, the current/voltage diagrams 400, 450 show
a sixth current/voltage curve 402 representing three serially coupled diodes, each having a diode area of 10 μm².
a seventh current/voltage curve 404 representing three serially coupled diodes, each having a diode area of 5 μm².
an eighth current/voltage curve 406 representing five serially coupled diodes, each having a diode area of 10 μm², and
a ninth current/voltage curve 408 representing five serially coupled diodes, each having a diode area of 5 μm².

In the linear scale shown in FIG. 4A, the regime becomes obvious where, in an embodiment of the invention, the diode stack is dominated by its series resistance in rather strong dependence from the diode area. The logarithmic scale shown in FIG. 4B shows the regime where the current is dominated by the exponential behaviour, which in an embodiment of the invention, is rather strongly dependent from the number of diodes in a serial connection.

It should be mentioned that care should be taken that the leakage current is not too high. The maximum acceptable leakage current should be chosen and the protection should be adjusted such that the leakage current does not get higher than the allowed chosen maximum. This can be adjusted as shown in FIG. 2, e.g., by appropriately selecting the number of the diodes 206, 208.

By choosing a different number of diodes 206, 208 (e.g., np-diodes or pn-diodes), the onset of the forward protection current can also be adjusted differently for every polarization.

One effect of the protection is dependent on the series resistance of the discharging path (provided, e.g., by a respective one of the two diode subcircuits 202, 204) during charging, e.g., in a plasma process. The series resistance may depend on the number of diodes but also on the area (i.e., size) of the diodes. By using larger diodes, the series resistance may be further decreased. In an embodiment of the invention, the area of the diodes may still be much smaller than in a conventional antenna protection diode.

The influence of the diode stack is shown in FIG. 3 for a different number of diodes in a stack. Because the currents during the charging are quite small (50 mA/cm²) diodes with a very small area are sufficient to realize a sufficiently high protection.

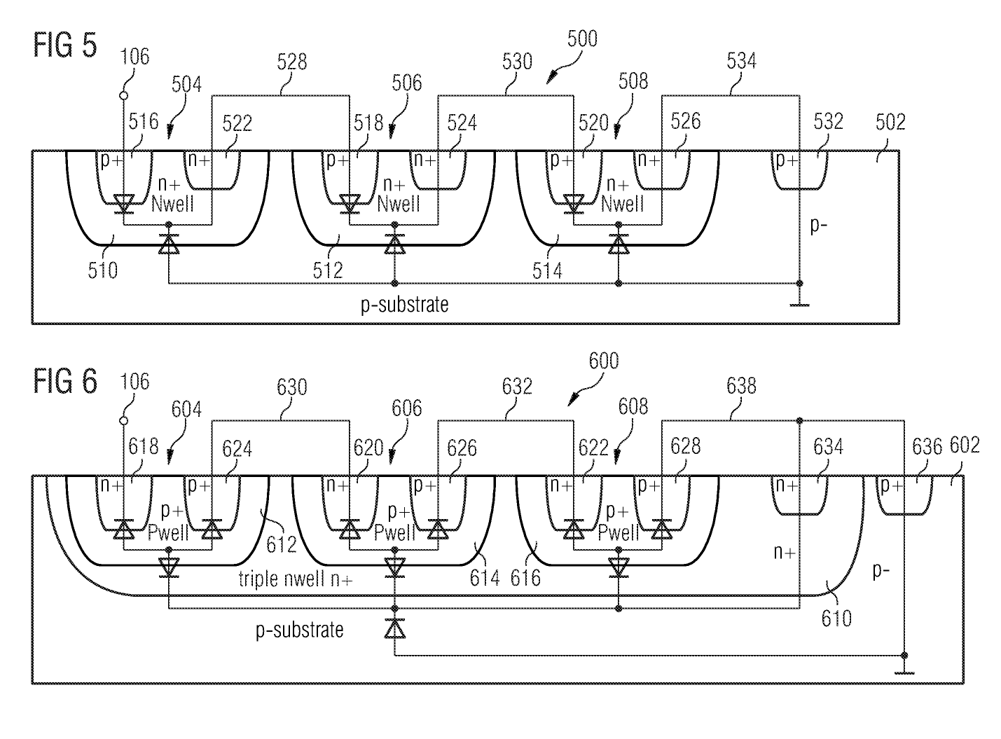

FIG. 5 shows a plurality 500 of serially coupled pn diodes (which may, e.g., form the first diode subcircuit 202) in accordance with an embodiment of the invention.

As shown in FIG. 5, a substrate 502 is provided. In an embodiment of the invention, the substrate 502 may be a wafer substrate 502. The wafer substrate 502 may be made of semiconductor material, although in another embodiment of the invention, other suitable materials can also be used. In an exemplary embodiment of the invention, the wafer substrate 502 is made of silicon (doped or undoped, e.g., p doped or p⁻ doped or n doped or n⁻ doped), in an alternative embodiment of the invention, the wafer substrate 502 is a silicon on insulator (SOI) wafer. As an alternative, any other suitable semiconductor materials can be used for the wafer substrate 502, for example, semiconductor compound material such as gallium arsenide (GaAs), indium phosphide (InP), but also any suitable ternary semiconductor compound material or quaternary semiconductor compound material such as indium gallium arsenide (InGaAs). In this case, the diodes, which will be described in more detail below, may be formed using an appropriate well definition in the substrate material.

In an embodiment of the invention, a plurality of serially coupled diodes 504, 506, 508, are provided in the substrate 502, e.g., in the following manner.

For each diode 504, 506, 508 a respective well (e.g., n⁺ doped well in the case of a p doped substrate) 510, 512, 514 is provided. Furthermore, one (or more) p⁺ doped region(s) 516, 518, 520 and one (or more) n⁺ doped region(s) 522, 524, 526 is (are) provided in each of the wells 510, 512, 514. For reasons of simplicity, only three diodes 504, 506, 508 are shown, but any arbitrary number of diodes may be provided in each diode subcircuit in the described manner, e.g., four, five, six, etc. The p doped region 516 of the first well 510 may be coupled to the charge receiving region (e.g., to a pad connection), e.g., via the first terminal 106. The n⁺ doped region 522 of the first well 510 may be coupled to the p⁺ doped region 518 of the second well 512 by means of a first electrically conductive structure 528, e.g., a conductor track, e.g., made of poly-silicon or a metal such as e.g. copper or aluminum. The n⁺ doped region 524 of the second well 512 may be coupled to the p⁺ doped region 520 of the third well 514 by means of a second electrically conductive structure 530, e.g., a conductor track, e.g., made of poly-silicon or a metal such as, e.g., copper or aluminum. The n⁺ doped region 526 of the third well 514 in turn may be coupled to a p⁺ doped region 532 provided in the substrate 502 by means of a third electrically conductive structure 534, e.g., a conductor track, e.g., made of poly-silicon or a metal such as, e.g., copper or aluminum.

Thus, FIG. 5 schematically shows one realization of the first diode subcircuit 202, which may also be referred to as a protection diode stack. As described above, the pn diode stack may include a series of pn-junctions in different n-wells.

In an embodiment of the invention, the np diode stack may be provided in a triple well structure as will be described in more detail below with reference to FIG. 6.

FIG. 6 shows a plurality 600 of serially coupled np diodes (which may, e.g., form the second diode subcircuit 204) in accordance with an embodiment of the invention.

As shown in FIG. 6, a substrate 602 is provided. In an embodiment of the invention, the substrate 602 may be a wafer substrate 602. The wafer substrate 602 may be made of semiconductor material, although in another embodiment of the invention, other suitable materials can also be used. In an exemplary embodiment of the invention, the wafer substrate 602 is made of silicon (doped or undoped, e.g., p doped or p⁻ doped or n doped or n⁻ doped), in an alternative embodiment of the invention, the wafer substrate 602 is a silicon on insulator (SOI) wafer. As an alternative, any other suitable semiconductor materials can be used for the wafer substrate 602, for example, semiconductor compound material such as gallium arsenide (GaAs), indium phosphide (InP), but also any suitable ternary semiconductor compound material or quaternary semiconductor compound material such as indium gallium arsenide (InGaAs). In this case, the diodes, which will be described in more detail below, may be formed using an appropriate well definition in the substrate material.

In an embodiment of the invention, a plurality of serially coupled diodes 604, 606, 608, are provided in the substrate 602, e.g., in the following manner.

A triple n⁺ doped well 610 is provided in the substrate 602. Furthermore, for each diode 604, 606, 608, a respective well (e.g., p⁺ doped well in the case of a p doped substrate and the triple n⁺ doped well 610) 612, 614, 616 is provided. Furthermore, one (or more) n⁺ doped region(s) 618, 620, 622 and one (or more) p⁺ doped region(s) 624, 626, 628 is (are) provided in each of the wells 612, 614, 616. For reasons of simplicity, only three diodes 604, 606, 608 are shown, but any arbitrary number of diodes may be provided in each diode subcircuit in the described manner, e.g., four, five, six, etc. The n⁺ doped region 618 of the first well 612 may be coupled to the charge receiving region (e.g., to a pad connection), e.g., via the first terminal 106. The p⁺ doped region 624 of the first well 612 may be coupled to the n⁺ doped region 620 of the second well 614 by means of a first electrically conductive structure 630, e.g., a conductor track, e.g., made of poly-silicon or a metal such as, e.g., copper or aluminum. The p⁺ doped region 626 of the second well 614 may be coupled to the n⁺ doped region 622 of the third well 616 by means of a second electrically conductive structure 632, e.g., a conductor track, e.g., made of poly-silicon or a metal such as, e.g., copper or aluminum. The p⁺ doped region 628 of the third well 616 in turn may be coupled to an n⁺ doped region 634 provided in the triple n⁺ doped well 610 and to a p⁺ doped region 636 provided in the substrate 602 by means of a third electrically conductive structure 638, e.g., a conductor track, e.g., made of poly-silicon or a metal such as, e.g., copper or aluminum.

Thus, FIG. 6 schematically shows one realization of the second diode subcircuit 204, which may also be referred to as a protection diode stack. As described above, the np diode stack may include a series of np-junctions in different p-wells.

In an embodiment of the invention, the triple well is contacted to ground (i.e., to the ground potential, in an alternative embodiment of the invention, to another reference potential) for a proper isolation from the substrate 602. If for a negative polarity only one diode is needed, as in the case of a normal integrated circuit (substrate is on the smallest possible potential) the triple well is provided.

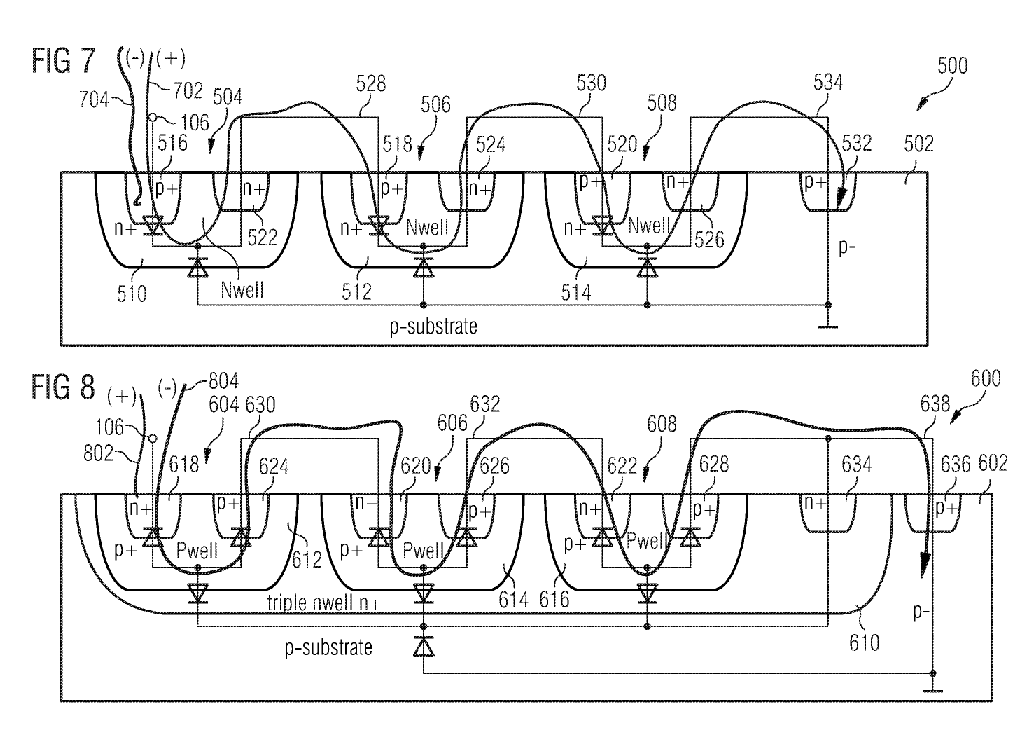

FIG. 7 shows the current paths (a first current path 702 for a positive potential (+) at the first terminal 106 and a second current path 704 for a negative potential (−) at the first terminal 106) for electrically discharging for different polarities for the plurality 500 of serially coupled pn diodes shown in FIG. 5 in accordance with an embodiment of the invention.

FIG. 8 shows the current paths (a first current path 802 for a positive potential (+) at the first terminal 106 and a second current path 804 for a negative potential (−) at the first terminal 106) for electrically discharging for different polarities for the plurality 600 of serially coupled np diodes shown in FIG. 6 in accordance with an embodiment of the invention.

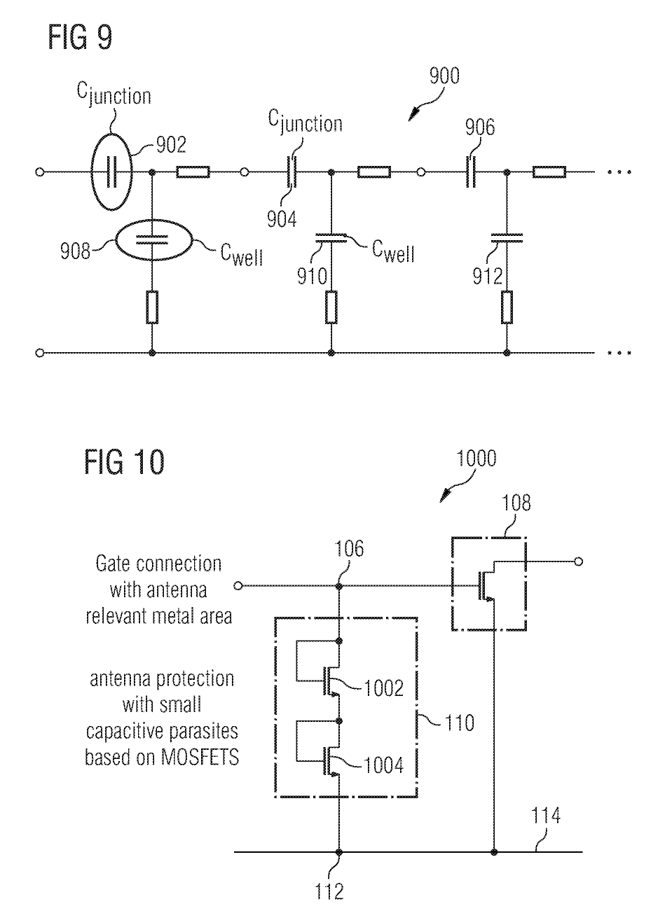

FIG. 9 shows a small signal equivalent circuit 900 of a diode subcircuit in accordance with an embodiment of the invention.

As shown in FIG. 9, the parasitic capacitive load mainly consists of the first diode (a first junction capacitance 902 of a plurality of junction capacitances C_{junction} 902, 904, 906) in series with the first well capacitance 908 of a plurality of well capacitances C_{well} 908, 910, 912 and can be chosen to be very small.

In an embodiment of the invention, the diode stack acts as an RF capable protection of a transistor gate from antenna charging degradation.

A further optimization can be realized in an embodiment of the invention by choosing different geometries for the first and the following diodes. Thus, the capacitive parasites can be realized small by the first diode while the series resistance can be decreased by choosing larger diodes for the subsequent diodes.

FIG. 10 shows an embodiment of a protection circuit portion 1000 of an integrated circuit in accordance with an embodiment of the invention, wherein only one polarity of protection is realized.

In this embodiment it is assumed that only one polarity of protection is required, e.g., because only one polarity of charge loadings can occur or because the protection of the other polarity of charge loadings accomplished in a different circuit.

In an embodiment of the invention, MOSFETs are used instead of diodes in the rectifying circuit 110, wherein the MOSFETs are connected in diode connection. Furthermore, the embodiment shown in FIG. 10 could also be provided with diodes instead of the MOSFETs. As described above, the rectifying circuit 110 may also be provided with thyristors coupled in a rectifying coupling structure or providing a rectifying functionality for only one polarity of charge loadings.

In more detail, in an embodiment of the invention, the rectifying circuit 110 includes a first MOSFET 1002 being coupled in diode connection and a second MOSFET 1004 being coupled in diode connection, wherein the first MOSFET 1002 and the second MOSFET 1004 are coupled in series with each other. Furthermore, the drain of the first MOSFET 1002 is coupled to the first terminal (also referred to as first node) 106 and to the gate of the first MOSFET 1002. The sources of the first and second first MOSFETs 1002, 1004 are coupled with each other and the drain of the second MOSFET 1004 is coupled to the second terminal 112 on the opposite side (also referred to as output side) of the rectifying circuit 110 and to the gate of the second MOSFET 1004.

Thus, in an embodiment of the invention, only one subcircuit, thereby providing exactly one current path in exactly one flow direction. In an embodiment of the invention, the rectifying circuit 110 includes a plurality of rectifying elements being coupled in series with each other to provide the protection for one polarity of charge loadings.

In an embodiment of the invention, a semiconductor manufacturing process charge protection circuit may include a first terminal coupled to a charge receiving region, a second terminal providing a discharge path, and a rectifying circuit coupled between the first terminal and the second terminal, the rectifying circuit comprising at least two anti-parallel coupled rectifying components.

In an embodiment of the invention, the charge receiving region includes metal.

In another embodiment of the invention, the charge receiving region includes an area having antenna characteristics.

In an embodiment of the invention, the semiconductor manufacturing process charge protection circuit further includes a circuit, which is sensitive to capacitive parasites, coupled to the charge receiving region.

Furthermore, the circuit, which is sensitive to capacitive parasites, may be a high frequency circuit.

In an embodiment of the invention, the semiconductor manufacturing process charge protection circuit further includes a coil coupled to the charge receiving region, wherein the coil may be part of an oscillator circuit or part of an amplifier circuit.

Furthermore, the second terminal may be coupled to a reference potential. The reference potential may be an electrical circuit ground potential.

In an embodiment of the invention, the semiconductor manufacturing process charge protection circuit further includes an electronic element coupled to the first terminal and to the charge receiving region.

The electronic element may be a transistor coupled to the first terminal and to the charge receiving region.

The control terminal of the transistor may be coupled to the first terminal and to the charge receiving region.

The transistor may be a field effect transistor or a bipolar transistor.

In an embodiment of the invention, the transistor is a field effect transistor, wherein the gate terminal of the field effect transistor is coupled to the first terminal and to the charge receiving region.

A first controlled terminal of the transistor may be coupled to a load circuit and a second controlled terminal of the transistor may be coupled to the reference potential.

In an embodiment of the invention, the rectifying circuit includes a first rectifying subcircuit comprising a plurality of serially coupled rectifying components, wherein the rectifying components of the first rectifying subcircuit are all connected in the same flow direction, and a second rectifying subcircuit comprising a plurality of serially coupled rectifying components, wherein the rectifying components of the second rectifying subcircuit are all connected in the same flow direction, wherein the rectifying components of the first rectifying subcircuit are coupled anti-parallel to the rectifying components of the second rectifying sub circuit.

In an embodiment of the invention, the rectifying components of the first rectifying subcircuit are pn-diodes, wherein the p-terminal of a first diode of the first rectifying subcircuit is coupled to the first terminal and the n-terminal of a last diode of the first rectifying subcircuit is coupled to the second terminal, and the rectifying components of the second rectifying subcircuit are np-diodes, wherein the n-terminal of a first diode of the second rectifying subcircuit is coupled to the first terminal and the p-terminal of a last diode of the second rectifying subcircuit is coupled to the second terminal.

In another embodiment of the invention, an integrated circuit is provided, which may include a charge receiving region, an electronic element, a semiconductor manufacturing process charge protection circuit, the semiconductor manufacturing process charge protection circuit having a first terminal coupled to the charge receiving region and to the electronic element, a second terminal providing a discharge path, and a rectifying circuit coupled between the first terminal and the second terminal, the rectifying circuit comprising at least two anti-parallel coupled rectifying components.

The charge receiving region may include metal.

Furthermore, the charge receiving region may include an area having antenna characteristics.

In an embodiment of the invention, the semiconductor manufacturing process charge protection circuit further includes a circuit, which is sensitive to capacitive parasites, coupled to the charge receiving region. The circuit, which is sensitive to capacitive parasites, may be a high frequency circuit.

In an embodiment of the invention, the semiconductor manufacturing process charge protection circuit further includes a coil coupled to the charge receiving region, wherein the coil is part of an oscillator circuit or part of an amplifier circuit.

The second terminal may be coupled to a reference potential. The reference potential may be an electrical circuit ground potential.

Furthermore, the electronic element may be a transistor coupled to the first terminal and to the charge receiving region.

In an embodiment of the invention, the control terminal of the transistor is coupled to the first terminal and to the charge receiving region.

Furthermore, in an embodiment of the invention, the transistor is a field effect transistor or a bipolar transistor.

By way of example, in the case that the transistor is a field effect transistor, the gate terminal of the field effect transistor may be coupled to the first terminal and to the charge receiving region.

A first controlled terminal of the transistor may be coupled to a load circuit, and a second controlled terminal of the transistor may be coupled to the reference potential.

In an embodiment of the invention, the rectifying circuit includes a first rectifying subcircuit comprising a plurality of serially coupled rectifying components, wherein the rectifying components of the first rectifying subcircuit are all connected in the same flow direction, and a second rectifying subcircuit comprising a plurality of serially coupled rectifying components, wherein the rectifying of the second rectifying subcircuit are all connected in the same flow direction. The rectifying components of the first rectifying subcircuit may be coupled anti-parallel to the rectifying components of the second rectifying subcircuit.

In an embodiment of the invention, the rectifying components of the first rectifying subcircuit are pn-diodes, wherein the p-terminal of a first diode of the first rectifying subcircuit is coupled to the first terminal and the n-terminal of a last diode of the first rectifying subcircuit is coupled to the second terminal, and the rectifying components of the second rectifying subcircuit are np-diodes, wherein the n-terminal of a first diode of the second rectifying subcircuit is coupled to the first terminal and the p-terminal of a last diode of the second rectifying subcircuit is coupled to the second terminal.

In another embodiment of the invention, a semiconductor manufacturing process charge protection circuit is provided. In this embodiment, the semiconductor manufacturing process charge protection circuit includes a first terminal coupled to a charge receiving region, a second terminal providing a discharge path, and a rectifying means coupled between the first terminal and the second terminal, the rectifying means comprising at least two anti-parallel coupled rectifying components.

In yet another embodiment of the invention, a semiconductor manufacturing process charge protection circuit is provided. In this embodiment, the semiconductor manufacturing process charge protection circuit includes a first terminal coupled to a charge receiving region, a second terminal providing a discharge path, and a rectifying circuit coupled between the first terminal and the second terminal, the diode circuit comprising a plurality of serially coupled rectifying components, wherein the rectifying components are all connected in the same flow direction.

The charge receiving region may include metal.

Furthermore, the charge receiving region may include an area having antenna characteristics.

In an embodiment of the invention, the semiconductor manufacturing process charge protection circuit further includes a circuit, which is sensitive to capacitive parasites, coupled to the charge receiving region.

The circuit, which is sensitive to capacitive parasites, may be a high frequency circuit.

In an embodiment of the invention, the semiconductor manufacturing process charge protection circuit further includes a coil coupled to the charge receiving region, wherein the coil may be part of an oscillator circuit or part of an amplifier circuit.

In yet another embodiment of the invention, the semiconductor manufacturing process charge protection circuit further includes an electronic element coupled to the first terminal and to the charge receiving region.

The electronic element may be a transistor coupled to the first terminal and to the charge receiving region.

Furthermore, in an embodiment of the invention, the rectifying circuit includes a first rectifying subcircuit comprising a plurality of serially coupled rectifying components, wherein the rectifying components of the first rectifying subcircuit are all connected in the same flow direction, and a second rectifying subcircuit comprising a plurality of serially coupled rectifying components, wherein the rectifying components of the second rectifying subcircuit are all connected in the same flow direction.

In an embodiment of the invention, an integrated circuit is provided. The integrated circuit includes a charge receiving region, an electronic element, and a semiconductor manufacturing process charge protection circuit. The semiconductor manufacturing process charge protection circuit may include a first terminal coupled to the charge receiving region and to the electronic element, a second terminal providing a discharge path, and a rectifying circuit coupled between the first terminal and the second terminal, the diode circuit having a plurality of serially coupled rectifying components, wherein the rectifying components are all connected in the same flow direction.

The charge receiving region may include metal.

Furthermore, the charge receiving region may include an area having antenna characteristics.

In an embodiment of the invention, the integrated circuit further includes a circuit, which is sensitive to capacitive parasites, coupled to the charge receiving region. The circuit, which is sensitive to capacitive parasites, may be a high frequency circuit.

In an embodiment of the invention, the integrated circuit further includes a coil coupled to the charge receiving region, wherein the coil may be part of an oscillator circuit or part of an amplifier circuit.

In an embodiment of the invention, the rectifying circuit includes a first rectifying subcircuit comprising a plurality of serially coupled rectifying components, wherein the rectifying components of the first rectifying subcircuit are all connected in the same flow direction, and a second rectifying subcircuit comprising a plurality of serially coupled rectifying components, wherein the rectifying of the second rectifying subcircuit are all connected in the same flow direction.

In yet another embodiment of the invention, a method for manufacturing a semiconductor manufacturing process charge protection circuit is provided. The method includes forming a first terminal coupled to a charge receiving region, forming a second terminal providing a discharge path, and forming a rectifying circuit coupled between the first terminal and the second terminal, the rectifying circuit comprising at least two anti-parallel coupled rectifying components.

In yet another embodiment of the invention, a method for manufacturing a semiconductor manufacturing process charge protection circuit is provided. The method includes forming a first terminal coupled to a charge receiving region, forming a second terminal providing a discharge path, and forming a rectifying circuit coupled between the first terminal and the second terminal, the diode circuit comprising a plurality of serially coupled rectifying components, wherein the rectifying components are all connected in the same flow direction.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A semiconductor manufacturing process charge protection circuit comprising:
a first terminal coupled to a charge receiving region;
a second terminal providing a discharge path; and
a rectifying circuit coupled between the first terminal and the second terminal, the rectifying circuit comprising at least two anti-parallel coupled rectifying components.

2. The semiconductor manufacturing process charge protection circuit of claim 1, wherein the charge receiving region comprises metal.

3. The semiconductor manufacturing process charge protection circuit of claim 1, wherein the charge receiving region comprises an area having antenna characteristics.

4. The semiconductor manufacturing process charge protection circuit of claim 1, further comprising a circuit, which is sensitive to capacitive parasites, coupled to the charge receiving region.

5. The semiconductor manufacturing process charge protection circuit of claim 4, wherein the circuit, which is sensitive to capacitive parasites, is a high frequency circuit.

6. The semiconductor manufacturing process charge protection circuit of claim 1, further comprising a coil coupled to the charge receiving region.

7. The semiconductor manufacturing process charge protection circuit of claim 6, wherein the coil is part of an oscillator circuit or part of an amplifier circuit.

8. The semiconductor manufacturing process charge protection circuit of claim 1, wherein the second terminal is coupled to a reference potential.

9. The semiconductor manufacturing process charge protection circuit of claim 1, further comprising an electronic element coupled to the first terminal and to the charge receiving region.

10. The semiconductor manufacturing process charge protection circuit of claim 1, wherein the rectifying circuit comprises:
a first rectifying subcircuit comprising a plurality of serially coupled rectifying components, wherein the rectifying components of the first rectifying subcircuit are all connected in the same flow direction; and
a second rectifying subcircuit comprising a plurality of serially coupled rectifying components, wherein the rectifying components of the second rectifying subcircuit are all connected in the same flow direction, wherein the rectifying components of the first rectifying subcircuit are coupled anti-parallel to the rectifying components of the second rectifying sub circuit.

11. An integrated circuit comprising:
a charge receiving region;
an electronic element; and
a semiconductor manufacturing process charge protection circuit, the semiconductor manufacturing process charge protection circuit comprising
a first terminal coupled to the charge receiving region and to the electronic element,
a second terminal providing a discharge path, and
a rectifying circuit coupled between the first terminal and the second terminal, the rectifying circuit comprising at least two anti-parallel coupled rectifying components.

12. The integrated circuit of claim 11, wherein the charge receiving region comprises metal.

13. The integrated circuit of claim 11, wherein the charge receiving region comprises an area having antenna characteristics.

14. The integrated circuit of claim 11, further comprising a circuit, which is sensitive to capacitive parasites, coupled to the charge receiving region.

15. The integrated circuit of claim 14, wherein the circuit, which is sensitive to capacitive parasites, is a high frequency circuit.

16. The integrated circuit of claim 11, further comprising a coil coupled to the charge receiving region.

17. The integrated circuit of claim 16, wherein the coil is part of an oscillator circuit or part of an amplifier circuit.

18. The integrated circuit of claim 11, wherein the second terminal is coupled to a reference potential.

19. The integrated circuit of claim 11, wherein the rectifying circuit comprises:
a first rectifying subcircuit comprising a plurality of serially coupled rectifying components, wherein the rectifying components of the first rectifying subcircuit are all connected in the same flow direction; and
a second rectifying subcircuit comprising a plurality of serially coupled rectifying components, wherein the rectifying of the second rectifying subcircuit are all connected in the same flow direction, wherein the rectifying components of the first rectifying subcircuit are coupled anti-parallel to the rectifying components of the second rectifying subcircuit.

20. A semiconductor manufacturing process charge protection circuit comprising:
a first terminal coupled to a charge receiving region;
a second terminal providing a discharge path; and
a rectifying circuit coupled between the first terminal and the second terminal, the rectifying circuit comprising a plurality of serially coupled rectifying components, wherein the rectifying components are all connected in the same flow direction.

21. The semiconductor manufacturing process charge protection circuit of claim 20, wherein the charge receiving region comprises metal.

22. The semiconductor manufacturing process charge protection circuit of claim 21, wherein the charge receiving region comprises an area having antenna characteristics.

23. The semiconductor manufacturing process charge protection circuit of claim 21, further comprising a circuit, which is sensitive to capacitive parasites, coupled to the charge receiving region.

24. An integrated circuit comprising:
a charge receiving region;
an electronic element; and
a semiconductor manufacturing process charge protection circuit, the semiconductor manufacturing process charge protection circuit comprising
a first terminal coupled to the charge receiving region and to the electronic element,
a second terminal providing a discharge path, and
a rectifying circuit coupled between the first terminal and the second terminal, the rectifying circuit comprising a plurality of serially coupled rectifying components, wherein the rectifying components are all connected in the same flow direction.

25. A method for manufacturing a semiconductor manufacturing process charge protection circuit, the method comprising:
forming a first terminal coupled to a charge receiving region;
forming a second terminal providing a discharge path; and
forming a rectifying circuit coupled between the first terminal and the second terminal, the rectifying circuit comprising at least two anti-parallel coupled rectifying components.
